(19) United States
(12) Patent Application Publication
(10) Pub. No.: US 2011/0279955 A1
(43) Pub. Date: Nov. 17, 2011

(54) PERIPHERAL DATA STORAGE DEVICE WITH DOCK CHARGE PASS-THROUGH CONNECTOR AND OPTIONAL MICROSD SLOTS AND ACCOMPANYING DEVICE AND HOST SOFTWARE FOR APPLE IPAD DEVICES

(76) Inventors: James T. Fahey, San Francisco, CA (US); Michael McGirr, Lafayette, CA (US)

(21) Appl. No.: 13/158,809

(22) Filed: Jun. 13, 2011

Related U.S. Application Data
(63) Continuation-in-part of application No. 12/581,768, filed on Oct. 19, 2009.
(60) Provisional application No. 61/106,809, filed on Oct. 20, 2008.

(51) Int. Cl. H05K 5/02

(52) U.S. Cl. 361/679.01

(57) ABSTRACT

A peripheral data storage device for Apple iPhone and iPod devices having an encasement containing a system of electronic circuits which communicates with the iPhone or iPod by means of a host software system and a device software system. The device also has a charge pass through connector and optional card slots. Various views of the device are shown in FIGS. 1-5.

### CROSS-REFERENCE TO RELATED APPLICATIONS

This application claims the benefit of provisional patent application EFS ID 4143296, Application No. 61106809, Confirmation Number 1621 filed Oct. 20,2008 by the above-mentioned inventors.

### FEDERALLY SPONSORED RESEARCH

Not Applicable

### SEQUENCE LISTING OR PROGRAM

Not Applicable

### BACKGROUND

### Field

This application relates to Apple iPhone and iPod peripherals, specifically to a peripheral device which stores data.

### DETAILED DESCRIPTION

### Hardware Form Factor (Encasement)

The Form Factor (Encasement) is shown in the drawings:

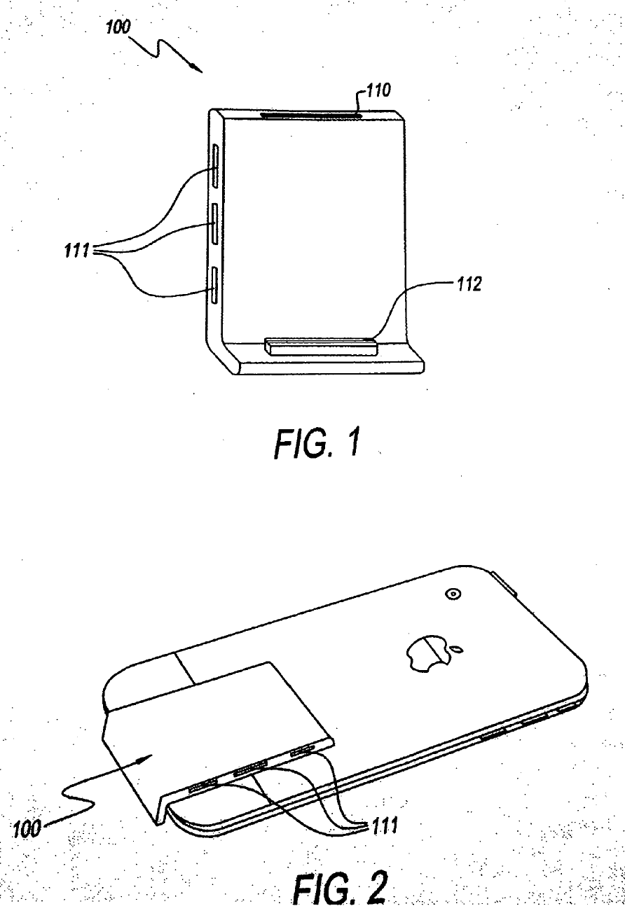

FIG. 1 shows the device disconnected from the iPhone, with dock pass-through connector, optional microSD slots, and dock connector for connection to iPhone.

FIG. 2 is a view of the back side of the iPhone with the device connected, showing the optional microSD slots.

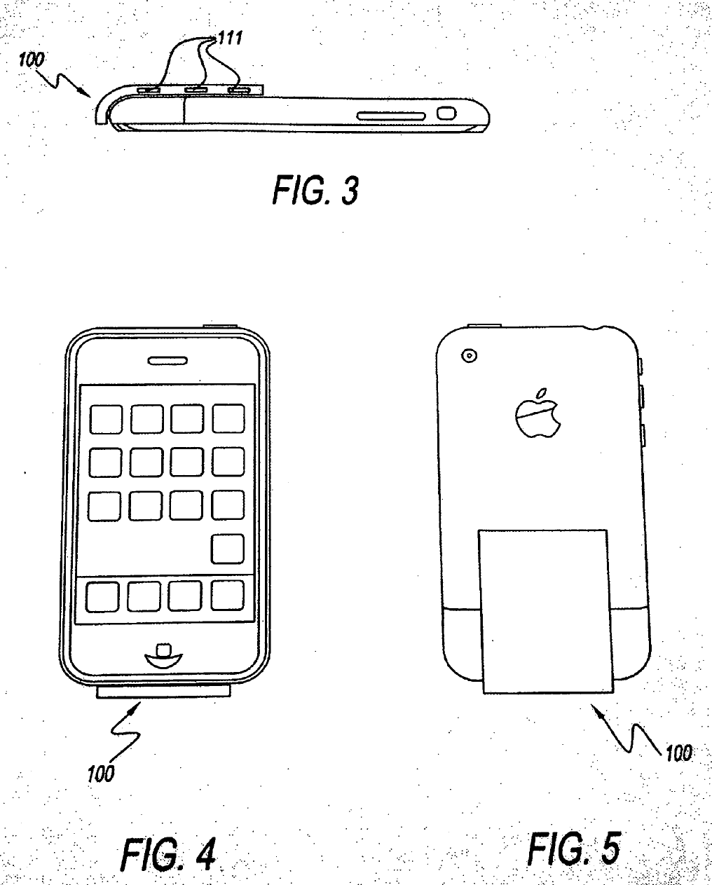

FIG. 3 is a side view of the device on the iPhone, showing the optional microSD slots

FIG. 4 is a frontal view of the iPhone with the device attached.

FIG. 5 is a rear view of the iPhone with the device attached.

### HARDWARE CONTENTS (SYSTEM OF ELECTRICAL CIRCUITS)

The contents of the above packaging will contain any number of the following electrical components as well as any other electrical components which might be necessary for operation:
Memory Components
Memory Cards
Controllers
PCBs
Interconnect
Capacitors
Oscillators

### Device Software

The software of the storage device will contain any number of the following items as well as any other software that might be necessary for operation of the storage device:
Memory Management Software (Error Correction, Wear Leveling, etc.)
Custom Content (Data, Video, Images, Music, Documents, etc.)
Security
Digital Rights Management
   Host (iPod or iPhone) Software

The software of the host (iPod or iPhone) will contain any number of the following items as well as any other software that might be necessary for operation of the host with the storage device:
Host Application Interface Software
Data Translation Software
Memory Management Software
Content
Content Enabling Software
Security
Digital Rights Management

### OPERATION

In operation one uses the storage device 100 as an attachment to the iPhone or iPOD. The storage device and host software allow the user to record content, store it on the storage device, retrieve the content in a secure way, and display/play the content on the host device. The user may install the host software by downloading it from the Internet. Or, the software may come pre-loaded on either the host or the storage device. Multiple hosts will be able to operate with the same card (device) in accordance with security and digital rights management.

The Pass-through Connector 110 allows the user to connect additional devices (such as chargers) to the iPhone or iPod while keeping the storage device attached and operational.

The optional microSD slots 111 allow the user to insert microSD cards into the storage device and record content, store it on the microSD cards, retrieve the content from the microSD cards in a secure way, and display/play the content from the microSD cards on the host iPod or iPhone device.

### ADVANTAGES

From the description above, it is evident that users who need additional memory for their iPhone or iPod now have a peripheral storage device which allows the user to record content, store it on the storage device, retrieve the content in a secure way, and display/play the content on the host device. Previously, these users had no way of extending the memory capabilities of their iPhone or iPod.

### CONCLUSION, RAMIFICATIONS, AND SCOPE

Accordingly, the reader will see that content makers (makers of video, music, maps, etc.) application makers (makers of games, GPS, live broadcasting, etc.) are no longer limited by the hardware present on the iPhone and iPod. Instead, content makers and application makers are now liberated to fully leverage the iPhone and iPod platform. Users, too, are freed from the limitations inherent to their iPhone or iPod device. As Moore's law continues to enable more and more memory, controller, data transmission speed, and software power for this peripheral device, there is virtually no limitation to the types of content and applications that can be used with the iPhone and iPod. The devices that have changed the world have now reached their maximum potential to content makers, application makers, and users alike!

We claim:

1. A machine, comprising:
a. an encasement for electronic circuits,
b. a system of electronic circuits mounted inside said encasement,
c. a device software means inside said system of electronic circuits for transmitting and receiving data to and from the iPhone or iPod device,
d. a host software means inside the iPhone or iPod for transmitting and receiving data to and from said system of electronic circuits,
I. whereby a user's iPod or iPhone has access to additional storage beyond that built in the iPod or iPhone.

2. The machine of claim 1 wherein said encasement has a pass through connector for connection with iPhone and iPod peripheral connections such as a charger.

3. The machine of claim 1 wherein said system of electronic circuits includes a memory card or cards.

4. The machine of claim 1 wherein said encasement includes slots for connection to memory cards.

5. The machine of claim 1 wherein said system of electronic circuits includes controller for the transmission and reception of data to and from the iPhone or iPod device wirelessly.

6. The machine of claim 1 wherein said encasement includes the iPhone's standard Dock Connector for transmission and reception of data to and from the iPod or iPhone directly.

7. The machine of claim 1 wherein said system of electronic circuits includes transmitter for the transmission and reception of data to and from the iPhone or iPod device wirelessly and said encasement includes the iPhone's standard Dock Connector for transmission and reception of data to and from the iPod or iPhone directly.

8. A method of transmitting and receiving data to and from a system of electronic systems comprising:
a. providing an encasement for electronic circuits,
b. mounting a system of electronic circuits inside said encasement,
c. loading a device software means into the said system of electronic circuits for transmitting and receiving data to and from the iPhone or iPod device,
d. loading a host software means into the iPhone or iPod device for transmitting and receiving data to and from the said system of electronic circuits.
i. whereby a user's iPod or iPhone has access to additional storage beyond that built in the iPod or iPhone.

9. The method of claim 8 wherein said encasement has a pass through connector for connection with iPhone and iPod peripheral connections such as a charger.

10. The method of claim 8 wherein said system of electronic circuits includes a memory card or cards.

11. The method of claim 8 wherein said encasement includes slots for connection to memory cards.

12. The method of claim 8 wherein said system of electronic circuits includes controller for the transmission and reception of data to and from the iPhone or iPod device wirelessly.

13. The method of claim 8 wherein said encasement includes the iPhone's standard Dock Connector for transmission and reception of data to and from the iPod or iPhone directly.

14. The method of claim 8 wherein said system of electronic circuits includes transmitter for the transmission and reception of data to and from the iPhone or iPod device wirelessly and said encasement includes the iPhone's standard Dock Connector for transmission and reception of data to and from the iPod or iPhone directly.
